(19) United States
(12) Patent Application Publication
(10) Pub. No.: US 2025/0072298 A1
(43) Pub. Date: Feb. 27, 2025

(54) ATOMIC-SCALE CLUSTER STORAGE AND COMPUTE DEVICE AND MANUFACTURING METHOD THEREOF

(71) Applicants: Jiangsu Jichuang Atomic Cluster Technology Research Institute Co., Ltd., Nanjing City (CN); Nanjing University, Nanjing (CN)

(72) Inventors: Fengqi SONG, Nanjing City (CN); Minhao ZHANG, Nanjing City (CN); Suyuan XIE, Nanjing City (CN); Wei JI, Nanjing City (CN); Yuanzhi TAN, Nanjing City (CN); Jun CHEN, Nanjing City (CN); Kangkang ZHANG, Nanjing City (CN); Bowen LIU, Nanjing City (CN); Luwei GU, Nanjing City (CN)

(21) Appl. No.: 18/655,948

(22) Filed: May 6, 2024

(30) Foreign Application Priority Data
Aug. 23, 2023 (CN) 2023110633461

(51) Int. Cl. H10N 60/10; H10N 60/01

(52) U.S. Cl. CPC H10N 60/128; H10N 60/01; H10N 60/11

(57) ABSTRACT

An atomic-scale cluster storage and compute device is successively provided with a substrate and oxide layer, a gate electrode, and a gate dielectric layer from bottom to top; at least one conductive electrode is provided on the gate dielectric layer, and one nanoscale gap is provided on each conductive electrode; two sides of the nanoscale gap are a source electrode and a drain electrode, and a combined molecular system is provided in the nanoscale gap; the combined molecular system is a composite system of one or more functional atoms and a single molecule, which forms good contact with a source electrode and a drain electrode, and the combined molecular system has the feature of a single electric dipole and bistable state. A combined molecular system of a single molecule with several functional atoms is constructed; the combined molecular system has the feature of a single electric dipole and bistable state.

### TECHNICAL FIELD

The present invention is in the field of information technology and particularly relates to an atomic-scale cluster storage and compute device and a manufacturing method thereof.

### BACKGROUND ART

Moore's law states that the number of transistors that can be integrated into a processor chip doubles every two years. However, as the degree of integration continues to increase, the feature size of transistors continues to shrink, and the size of the core elements decreases to a few nanometers, only a few tens of atoms in size, approaching the single-atom limit. Therefore, single-atom storage transistors are a future limit of current storage devices. In 2017, IBM demonstrated the concept of single-atom storage in a single magnetic atom based on a scanning tunneling microscope. However, systems based on a single bare magnetic atom have great difficulties in device integration at room temperature, and the approach based on a scanning tunneling microscope is not conducive to device integration.

Since 1950, it has been proposed to replace electronic components in the semiconductor industry with the properties of individual molecules. After a long development, various single-molecule devices such as molecular diodes, molecular field effect transistors, molecular switches, molecular sensors, and the like have been successively proposed. In 2002, Cornell University and others constructed atomic transistors using a single molecule, where it was explicitly stated that a single atomic transistor is not a transistor with only one atom (a single atom cannot in fact become a separate device), but a transistor that uses an electric field to manipulate the state of a single functional atom to achieve a device function. In 2017, IBM demonstrated the possibility of using a single functional atom for storage. In 2020, Nanjing University and other units discovered the single molecule electret effect and achieved stable storage for several months at a low temperature of 2 K. In 2022, Xiamen University and other units realized the storage operation of second scale at room temperature.

These efforts provide opportunities for developing atomic-scale storage transistors for platforms using single molecular devices. However, due to current technical bottlenecks, there is no clear solution to achieve stable and high-temperature single atomic-scale storage devices at the same time, further hindering the future demand for its integration.

### SUMMARY OF THE INVENTION

In order to solve the prior art problems, the present invention provides an atomic-scale storage and compute device and a manufacturing method thereof, which can greatly improve the success rate of the device, make the device be stored for a long time, and obtain a higher operating temperature. The present invention uses an anchor point-modified combined molecular system and designs a new structure of gate electrodes and source and drain electrodes so that the atomic-scale storage and compute device can achieve higher operating temperature, success rate, stability, and integration potential. Further, by the integration of the devices, a neural network having a storage and compute integrated function can be formed.

The atomic-scale cluster storage and compute device of the present invention is successively provided with a substrate and oxide layer, a gate electrode, and a gate dielectric layer from bottom to top; at least one conductive electrode is provided on the gate dielectric layer, and one nanoscale gap is provided on each conductive electrode, two sides of the nanoscale gap are a source electrode and a drain electrode, and a combined molecular system is provided in the nanoscale gap, the combined molecular system is a composite system of one or more functional atoms and a single molecule, which forms good contact with a source electrode and a drain electrode, and the combined molecular system has the feature of a single electric dipole and bistable state; the gate electrode is a conductive nanowire, and the conductive nanowire is a metal nanowire or a graphene nanowire or a silicon germanium atom wire.

Preferably, the combined molecular system is a endohedral fullerene molecular system.

Preferably, the feature of a single electric dipole and bistable state is characterized by a single molecular electret or a single molecular ferroelectric.

Preferably, the combined molecular system is subjected to a treatment of anchor point modification, so that the combined molecular system is combined with the source electrode and the drain electrode via an anchor point structure.

Preferably, the anchor point is thiol or amino or nitro or cyano, or heterocycle.

Preferably, the conductive electrode is in the shape of an hourglass with point contact, and the nanoscale gap is located at the finest part of the hourglass.

Preferably, the material of the conductive electrode is gold, silver, copper, platinum, nickel, or indium.

Preferably, the substrate is monocrystalline silicon, strontium titanate, mica, sapphire, or glass; the oxide layer is silicon oxide, silicon nitride, aluminum oxide, hafnium oxide, or doped hafnium oxide.

The manufacturing method of an atomic-scale cluster storage and compute device of the present invention includes the following steps:
S1: taking a substrate and oxide layer;
S2: fabricating a gate electrode on the oxide layer of the substrate and oxide layer;
S3: preparing a gate dielectric layer on an upper surface of the gate electrode;
S4: preparing a conductive electrode on an upper surface of the gate dielectric layer;
S5: forming a nanoscale gap by performing electromigration and disconnection on the conductive electrode, and forming a source electrode and a drain electrode at two sides of the nanoscale gap;
S6: dropping a readily volatile solution containing a combined molecule with a feature of a single electric dipole and bistable state onto the conductive electrode, and waiting for sufficient volatilization, so that the combined molecular system falls into the nanoscale gap and forms a coupling with the source electrode and the drain electrode; and
S7: applying a fixed bias voltage to the source electrode and the drain electrode, and applying voltages in different directions back and forth to the gate electrode, when the gate voltage exceeds a certain threshold, to achieve switching of atomic states within a molecular cage.

In the present invention, a combined molecular system of a single molecule with several functional atoms is constructed; the combined molecular system has the feature of a single electric dipole and bistable state; the combined molecular system is modified by an anchor point so that stable contact of the anchor point with the electrode increased. When an electric field is applied to an electrode, the bistable state of a single electric dipole is controllably switched, corresponding to the change of the position of a functional atom. By setting a program for detecting and switching the electric field, the function of initializing, accessing, and erasing “0” and “1” states is provided, so as to realize the storage operation of thermal data, etc. At the same time, the integration level of the storage and compute device is further improved by designing and developing the new structure of gate electrodes and source and drain electrodes.

### BRIEF DESCRIPTION OF THE DRAWINGS

FIG. 1 is a schematic view of the features of the combined molecular system of the present invention;

FIG. 2 is a schematic view of the features of the anchor point-modified combined molecular system of the present invention;

FIG. 3 is a logical schematic view of achieving non-volatile storage through the atomic storage of the present invention.

FIG. 4 is a schematic cross-sectional view of the atomic storage of the present invention. That is a simplified diagram (schematic view of the structure) of the device of the present invention.

FIG. 5 is a three-dimensional view of a three-terminal atomic storage of the present invention.

FIG. 6 is a schematic view of an atomic quantum storage of the present invention;

FIG. 7 is a graph of actual test results of the atomic-scale storage of the present invention at different temperatures for a period of time.

### REFERENCE NUMERALS

1—substrate and oxide layer, 2—gate electrode, 3—gate dielectric layer, 4—source electrode, 5—drain electrode.

Among which, the source electrode and drain electrode are known as source, drain.

### DETAILED DESCRIPTION OF THE INVENTION

The present invention will now be further described with reference to the following examples and accompanying drawings.

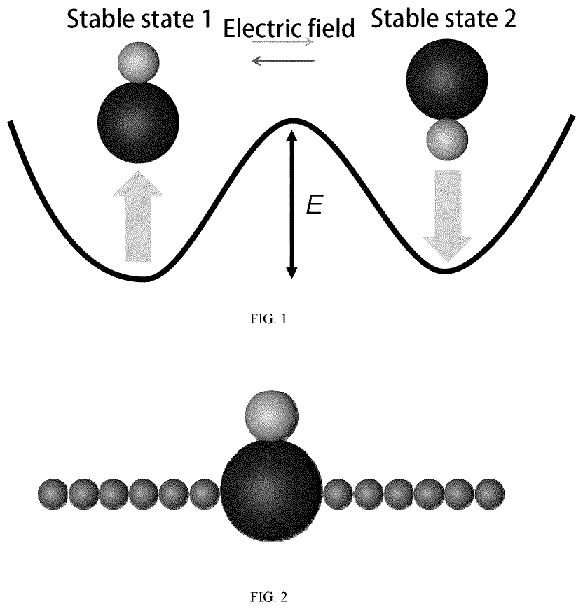

The atomic-scale cluster storage and compute device of the present invention includes a substrate and oxide layer 1, a gate electrode 2, and a gate dielectric layer 3 which are successively arranged from bottom to top, wherein at least one conductive electrode is provided on the gate dielectric layer 3, each conductive electrode is provided with a nanoscale gap, two sides of the nanoscale gap are a source electrode 4 and a drain electrode 5, and the nanoscale gap contains a combined molecular system which forms good contact with the source electrode 4 and the drain electrode 5 respectively. As shown in FIGS. 4-5, a simplified structure of the atomic-scale cluster storage and compute device of the present invention is shown. The combined molecular system has the feature of a single electric dipole and bistable state, as shown in FIG. 1.

The combined molecular system is a composite system of one or more functional atoms and a single molecule. The combined molecular system may be a endohedral fullerene molecular system. Such combined molecular systems, when containing a single functional atom, are referred to as single-atom storage and compute devices. The feature of a single electric dipole and bistable state may be characterized by particular a single molecular electret or single molecular ferroelectric feature.

As a preferred solution, the combined molecular system is subjected to an anchor point modification as shown in FIG. 2. By attaching specific structures on the outside of the combined molecular system, these structures have groups that are more capable of binding to the source electrode 4 and the drain electrode 5, these groups are called anchor points, and attaching these specific structures on the outside of the combined molecular system is a modification of the anchor points of the combined molecular system. As the anchor point, a thiol group, an amino group, a nitro group, a cyano group, a heterocyclic group, or the like can be specifically used. By modifying the anchor point of the combined molecular system, the combined molecular system has a stronger binding effect with the conductive electrode, thus leading to a better resistance to temperature disturbance, so that the storage and compute device can operate at a higher temperature. At the same time, the combined molecular system and the conductive electrode have a stronger binding effect, which also brings the storage and compute device resistance to the interference of potential difference, vibration, atomic displacement, and so on, improves the stability, and improves the working life.

As a preferred solution, gate electrode 2 is in the form of a conductive nanowire with the width of atoms, thereby improving the positioning of the combined molecular system and facilitating the integration of the storage. The conductive nanowires herein are specifically metal nanowires or graphene nanowires or silicon germanium atom wires, etc. The atom-wide conductive nanowires can be formed by electron beam evaporation, magnetron sputtering, thermal evaporation, pulsed laser deposition, chemical vapor deposition, or molecular beam epitaxy.

As a preferred solution, the conductive electrode has a structure in the shape of an hourglass with point contact, and the effect thereof is to make the position of the nanoscale gap more precise and close to the finest part of the hourglass, thereby facilitating further reduction in size and improvement in integration.

In the substrate and oxide layer 1, the substrate is one of a monocrystalline silicon layer, a strontium titanate layer, a mica layer, a sapphire layer, and glass; the oxide layer is one of a silicon oxide layer, a silicon nitride layer, an aluminum oxide layer, a hafnium oxide layer, or a doped hafnium oxide layer.

As a preferred solution, the material of the conductive electrode is one of gold, silver, copper, platinum, nickel, or indium layers, and the conductive electrode is formed by electron beam evaporation, magnetron sputtering, thermal evaporation, pulsed laser deposition, or molecular beam epitaxy.

As a preferred solution, the nanoscale gap may be formed by focused ion beam etching, mechanical methods, electromigration, chemical methods, or mask deposition methods, by which the position, direction, and size of the nanoscale gap are controlled, thereby controlling the fabrication accuracy of the storage and compute device.

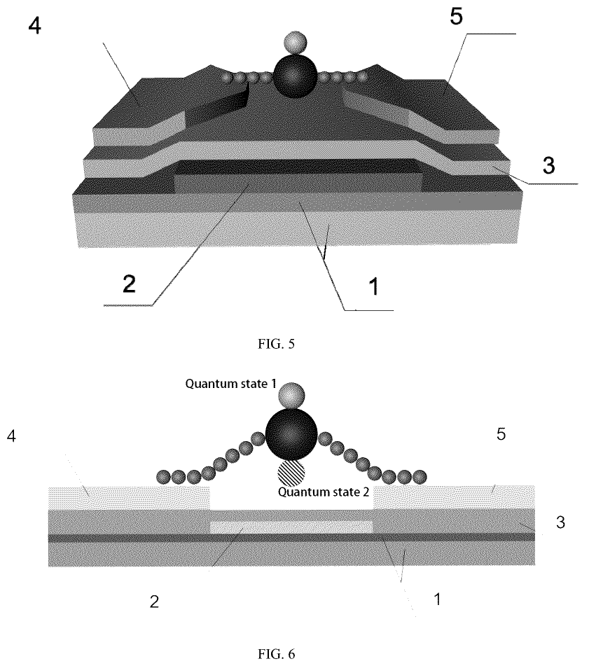

Before the operation of the atomic-scale cluster storage and compute device according to the present invention, the combined molecular system forms good contact with the source electrode 4 and the drain electrode 5 in the nanoscale gap. Switching of the quantum states of the device is achieved by adjusting the atomic states of the combined molecular system in the device by applying a voltage to the gate electrode 2, as shown in FIG. 6. The integration capability of the storage can be improved by the construction of a conductive nanowire with the width of atoms of the gate electrode 2 to achieve effective positioning of the molecules. Further, by the integration of the devices, a neural network having a storage and compute integrated function can be formed.

The manufacturing method of an atomic-scale cluster storage and compute device of the present invention specifically includes the following steps:
S1: taking a substrate and oxide layer;
S2: fabricating a gate electrode on the oxide layer of the substrate and oxide layer;
S3: preparing a gate dielectric layer on an upper surface of the gate electrode;
S4: preparing a conductive electrode on an upper surface of the gate dielectric layer;
S5: forming a nanoscale gap by performing electromigration and disconnection on the conductive electrode, and forming a source electrode and a drain electrode at two sides of the nanoscale gap;
S6: dropping a readily volatile solution containing a combined molecule with a feature of a single electric dipole and bistable state onto the conductive electrode, and waiting for sufficient volatilization, so that the combined molecular system falls into the nanoscale gap and forms a coupling with the source electrode and the drain electrode; and
S7: applying a fixed bias voltage to the source electrode and the drain electrode, and applying voltages in different directions back and forth to the gate electrode, when the gate voltage exceeds a certain threshold, to achieve switching of atomic states within a molecular cage.

The manufacturing method of an atomic-scale cluster storage and compute device according to the present invention can precisely control the position of a nanoscale gap and increase good contact between a combined molecular system and a source electrode 4 and a drain electrode 5, thereby increasing the integration capability of the manufactured storage and compute device.

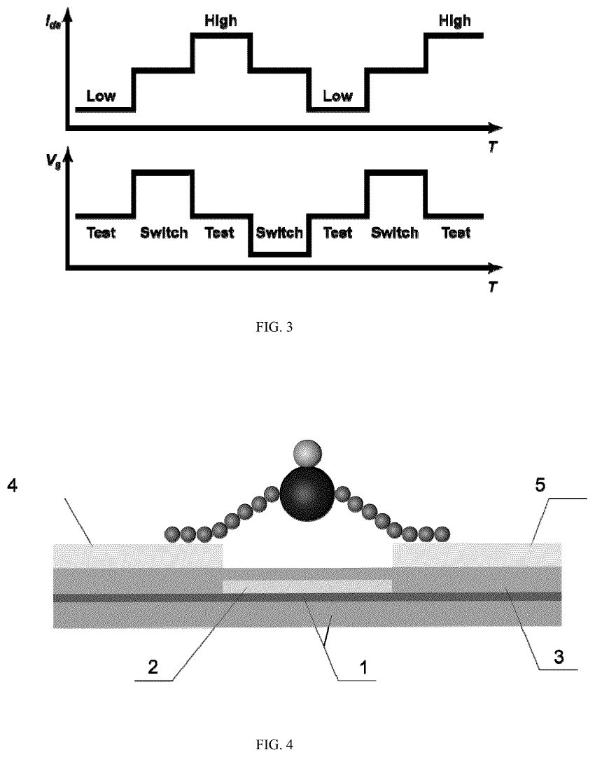

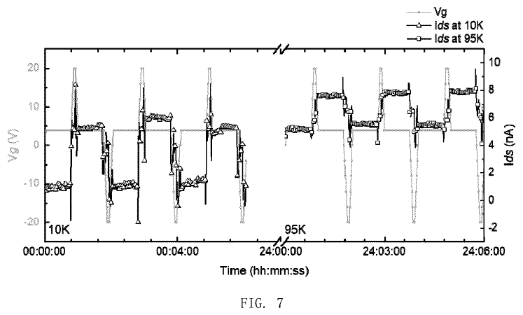

A manufacturing method of an atomic-scale cluster storage and compute device is described below with reference to specific embodiments:
S1. Monocrystalline silicon containing a 300 nm silicon oxide layer was selected as a substrate and oxide layer 1, an ultraviolet photolithography method was used to expose a target position of gate electrode 2, and other positions were protected by a photoresist. The substrate and oxide layer 1 was immersed into HF, and the original silicon oxide was removed by means of wet etching;
S2. An atomic layer deposition (ALD) method was used to re-grow a thin layer of silicon oxide of 30 nm as a gate dielectric layer 3 at the position where the silicon oxide has been etched away, thereby forming a thinner gate dielectric layer 3 so that the storage and compute device had a stronger gate regulation capability;
S3. A peripheral electrode was fabricated by using an ultraviolet photolithography and electron beam evaporation method so that a welding line was easily performed when measuring a storage and compute device; the peripheral electrode was composed of 5 nm-thick titanium and 150 nm-thick gold, with titanium as an adhesion layer;
S4. A conductive electrode was prepared by means of electron beam exposure and electron beam evaporation, wherein the conductive electrode was a gold nanowire; the gold nanowires were designed in the shape of an hourglass with point contact, the design width of the finest part was 10 nm, and the thickness was 20 nm; the shape of an hourglass with point contact helps to focus the position where the final nanoscale gap was formed;
S5. The device was loaded into a cryostat, the temperature was lowered to a liquid helium temperature, and electromigration was performed to form a nanoscale gap; a method of gradually thinning the electrodes by applying a voltage according to a conductivity feedback cycle was used to form a source electrode 4 and a drain electrode 5;
S6. A readily volatile solution of Gd@C₈₂(EDA)₈ molecules was added dropwise onto the prepared device, and after the solution was sufficiently volatilized, molecules were adsorbed on the surface of the device; the concentration of molecular solution was 0.1 mmol/L; Gd@C₈₂ molecule was a single molecular electret with an electric dipole moment, which could be controlled in two states by electric field; EDA was a modified ethylenediamine group on the periphery of the molecule, and the terminal amino group binds strongly to the gold electrode, which could serve as an anchor point to enhance the stability of molecular devices. A single molecule device was formed when Gd@C₈₂(EDA)₈ molecules fall into a nanoscale gap and form an appropriate coupling with a source electrode 4 and a drain electrode 5;
S7. A gate voltage-modulated molecular state of a device that had been successfully prepared and had a molecular transport behavior was measured: a fixed bias voltage of 2 mV was applied to the source electrode 4 and the drain electrode 5, and voltages in different directions back and forth were applied to the gate electrode 2; and when the gate voltage exceeded a certain threshold, switching the atomic states in the molecular cage will be realized, corresponding to different electronic states.
S8. Two sets of electronic states had different source and drain currents under the same gate voltage, the feature was used to regulate the gate voltage of the device, and the values of the source and drain current were taken as an output, which can be used as a non-volatile storage device. The specific method is shown in FIG. 3: here, the gate voltage +4 V is selected as the measured state, and the molecular state is changed by adjusting the gate voltage to ±20 V, so as to realize the switching of high and low source and drain current values at the gate voltage of +4 V. At the same time, since the anchor point structure forms a stable contact with the electrode, with increasing temperature, after the device is put for 24 hours when the temperature reaches 95 K, the device still maintains the two-state switching characteristic, as shown in FIG. 7.

In the above-mentioned implementation method, in steps S1 and S2, silicon itself of the silicon wafer of the substrate and oxide layer can be used as a bottom gate electrode, and a conductive nanowire can also be used as a gate electrode 2, and an oxide substance is used above same as a gate dielectric layer 3; using a conductive nanowire as the gate electrode 2 can make the gate dielectric layer 3 above this point have a convex arch shape. At this time, the evaporated gold nanowire is more prone to electromigration under the action of an electric field so as to form a nanoscale gap. The gate electrode 2 of this new structure further precisely locates the gap, which is helpful to the integration of the device. Wherein the electrode applies an electric field, and the electrode can be a gate electrode or a source and drain electrode. If an electric field is applied to the source electrode and drain electrode, the device may be a two-terminal device. The electric field includes a stable state electric field and a high-frequency electric field, etc. The high-frequency electric field includes microwave and terahertz waves, etc.

What has been described above is merely a preferred embodiment of the present invention. It should be noted that modifications and variations can be made by those skilled in the art without departing from the principles of the invention. Such modifications and variations should also be considered within the scope of the present invention.

1. An atomic-scale cluster storage and compute device, wherein the atomic-scale cluster storage and compute device is successively provided with a substrate and oxide layer, a gate electrode and a gate dielectric layer from bottom to top; at least one conductive electrode is provided on the gate dielectric layer, and one nanoscale gap is provided on each conductive electrode; two sides of the nanoscale gap are a source electrode and a drain electrode, and a combined molecular system is provided in the nanoscale gap; the combined molecular system is a composite system of one or more functional atoms and a single molecule, which forms good contact with the source electrode and the drain electrode, and the combined molecular system has a feature of a single electric dipole and bistable state; the gate electrode is a conductive nanowire, and the conductive nanowire is a metal nanowire or a graphene nanowire or a silicon germanium atom wire; the molecules with the feature of a single electric dipole and bistable state are Gd@C82(EDA) 8 molecules.

2. The atomic-scale cluster storage and compute device of claim 1, wherein the combined molecular system is a endohedral fullerene molecular system.

3. The atomic-scale cluster storage and compute device of claim 1, wherein the feature of a single electric dipole and bistable state is characterized by a single molecular electret or a single molecular ferroelectric.

4. The atomic-scale cluster storage and compute device of claim 1, wherein the combined molecular system is subjected to a treatment of anchor point modification, so that the combined molecular system is combined with the source electrode and the drain electrode via an anchor point structure.

5. The atomic-scale cluster storage and compute device of claim 4, wherein the anchor point is thiol or amino or nitro or cyano or heterocycle.

6. The atomic-scale cluster storage and compute device of claim 1, wherein the conductive electrode is in the shape of an hourglass with point contact, and the nanoscale gap is located at the finest part of the hourglass.

7. The atomic-scale cluster storage and compute device of claim 1, wherein the material of the conductive electrode is gold, silver, copper, platinum, nickel, or indium.

8. The atomic-scale cluster storage and compute device of claim 1, wherein the substrate is monocrystalline silicon, strontium titanate, mica, sapphire, or glass; the oxide layer is silicon oxide, silicon nitride, aluminum oxide, hafnium oxide, or doped hafnium oxide.

9. A manufacturing method of an atomic-scale cluster storage and compute device, comprising the following steps:
S1: taking a substrate and oxide layer;
S2: fabricating a gate electrode on the oxide layer of the substrate and oxide layer;
S3: preparing a gate dielectric layer on an upper surface of the gate electrode;
S4: preparing a conductive electrode on an upper surface of the gate dielectric layer;
S5: forming a nanoscale gap by performing electromigration and disconnection on the conductive electrode, and forming a source electrode and a drain electrode at two sides of the nanoscale gap;
S6: dropping a readily volatile solution containing a combined molecule with a feature of a single electric dipole and bistable state onto the conductive electrode, and waiting for sufficient volatilization, so that the combined molecular system falls into the nanoscale gap and forms a coupling with the source electrode and the drain electrode; and
S7: applying a fixed bias voltage to the source electrode and the drain electrode, and applying voltages in different directions back and forth to the gate electrode, when the gate voltage exceeds a certain threshold, to achieve switching of atomic states within a molecular cage.
